(19) United States
(12) Patent Application Publication
(10) Pub. No.: US 2019/0181129 A1
(43) Pub. Date: Jun. 13, 2019

(54) CONTINUOUS POWER RAILS ALIGNED ON DIFFERENT AXES

(71) Applicant: TEXAS INSTRUMENTS INCORPORATED, Dallas, TX (US)

(72) Inventors: Senthil Kumar SUNDARAMOORTHY, Bangalore (IN); Rakesh DIMRI, Bangalore (IN)

(21) Appl. No.: 15/840,418

(22) Filed: Dec. 13, 2017

(51) Int. Cl. H01L 27/02; H03K 19/08; H01L 23/528

(52) U.S. Cl. CPC H01L 27/0207; H01L 23/5286; H03K 19/08

(57) ABSTRACT

An apparatus comprising a first digital block, a second digital block, and a continuous power rail. The continuous power rail comprising a first portion, extending through the first digital block that is aligned along a first axis and the continuous power rail further comprising a second portion, extending through the second digital block that is aligned along a second axis, wherein the first and the second axes are parallel to each other.

### BACKGROUND

From a layout perspective, an integrated circuit (IC) may include multiple digital blocks, with each digital block performing some logical function. The cost of fabricating an IC may depend on the number of levels of metal layers that are utilized to route the electronic elements present in the digital blocks. In some cases, double or triple levels of metal layers are used to route the electronic elements present in the digital blocks.

### SUMMARY

According to an example, an apparatus comprising a first digital block, a second digital block, and a continuous power rail. The continuous power rail comprising a first portion, extending through the first digital block that is aligned along a first axis and the continuous power rail further comprising a second portion, extending through the second digital block that is aligned along a second axis, wherein the first and the second axes are parallel to each other.

According to another example, an apparatus, comprising a digital block and a power rail. The power rail comprising a first portion aligned along a first axis, a second portion aligned along a second axis, and a third portion aligned along a third axis that is orthogonal to the first and second axes, the third portion couples to the first portion and the second portion.

According to yet another example, an apparatus, comprising a digital block. The apparatus also comprising a first power rail comprising a first, a second, and a third portion, the first portion aligned along a first axis, the second portion aligned along a second axis, the third portion aligned along a third axis that is orthogonal to the first and second axes, the third portion couples the first portion and the second portion. The apparatus further comprising a second power rail comprising a fourth, a fifth, and a sixth portion, the fourth portion aligned along a fourth axis, the fifth portion aligned along a fifth axis, the sixth portion aligned along a sixth axis that is orthogonal to the fourth and fifth axes, the sixth portion couples to the fifth portion and the sixth portion.

### BRIEF DESCRIPTION OF THE DRAWINGS

For a detailed description of various examples, reference will now be made to the accompanying drawings in which:

FIG. 1(a) is an illustrative digital block area that employs a single level of global met layers and poly layers to transport signals between multiple digital blocks, in accordance with various examples.

FIG. 1(b) is a modified version of the illustrative digital block area of FIG. 1(a), in accordance with various examples.

FIGS. 2(a)-2(d) depicts an illustrative region of the modified digital block area, in accordance with various examples.

### DETAILED DESCRIPTION

The examples in this disclosure are directed towards an apparatus (such as an IC) that is fabricated by employing masks that are designed, at least in part, using layouts. These layouts are constructed using a cell-based methodology. Stated another way, the layouts facilitate the formation of masks, which are further employed to fabricate the IC. The cell-based methodology utilizes multiple digital blocks (or cells) to form the layouts. A digital block may not be explicitly identified in a fabricated IC. However, since the final fabricated IC may be derived from the masks that are designed using the cell-based methodology, the scope of the description herein is not limited to the layouts used to fabricate the IC, but also include the IC.

The semiconductor industry employs a cell-based methodology in order to segregate the logical aspect and the physical aspect of an IC. The cell-based methodology makes it possible for one designer to simulate (on a computer system) the design of an IC from a high-level (logical function), while another designer focuses on the implementation aspect of the logical design. The cell-based methodology assists in modularizing the logical function (e.g., muxed D-input flip-flop) of an IC into multiple smaller (modular) logical functions (e.g., NAND). The cell-based methodology does so by using multiple digital blocks (also referred to as “standard cells”) that can collectively perform the modularized logical function. Stated another way, multiple smaller digital blocks (e.g., NAND) may operate in tandem to perform a more complex logical function (e.g., muxed D-input flip-flop). A single digital block may generally be described as a group of electronic elements (e.g., transistors) that work together to perform one or more logical functions. A digital block may be readily identifiable on a circuit layout. For example, a circuit layout may represent a digital block using a rectilinear object that represents a group of electronic elements that work together to perform one or more logical functions. However, from a fabrication standpoint, a digital block may not necessarily be neatly circumscribed within rectilinear borders. In such cases, a digital block on a fabricated IC may be identified using the corresponding circuit layout and/or the mask(s) that were used in tandem with the layout to fabricate the IC. In some cases, multiple digital blocks performing a modularized logical function may employ a design that uses two levels of metal layers for routing purposes. Reducing the number of levels of met layers decreases costs due to the number of masks that must be used during manufacture, but using just one level of met layers may yield an unrouteable design. Thus, there is a need in the art to develop standard cell architecture that uses a single level of met layers to route multiple digital blocks.

As noted above, multiple electronic elements in a digital block include a plurality of transistors. A transistor includes a drain portion, a source portion and a gate portion. A polysilicon (poly) layer is typically employed to transport gate signals to the gate portions of the plurality of transistors. However, in some cases, the poly layer can be used as a routing layer. Thus, a combination of both the poly and a single level of met layers may be used for routing purposes. However, the standard cell methodology typically limits the amount of space designers may have to design a layout. Thus, in some cases, due to limited spatial constraints, additional space for the single level of met layers may be needed if the routing is to be completed using the poly and a single level of met layers.

Accordingly, at least some of the examples disclosed herein are directed towards a cell-based methodology that enables the incorporation of additional met layers in a single level. In particular, the examples disclosed herein may be applicable to the cell-based methodology that uses poly layers as routing layers. The disclosed systems provide techniques that facilitate incorporating additional met layers by changing the positions of power rails, which are typically present (in a typical cell-based architecture) at the periphery of a digital block (or the outermost periphery of the outermost electronic elements within the digital block). In particular, the disclosed system includes modified power rail positions. In some examples, these modified power rail positions are more proximate to a center of a digital block than they are to an outermost periphery of that digital block. In some examples, the modified power rail positions are more proximate to a center of a digital block than the outermost periphery of that digital block. Thus, the modified power rail position may provide additional space to facilitate the inclusion of additional routing layers. Additionally, the disclosed examples introduce jogs in the power rails, which further facilitate maintaining continuity in power rails that are present between multiple digital blocks.

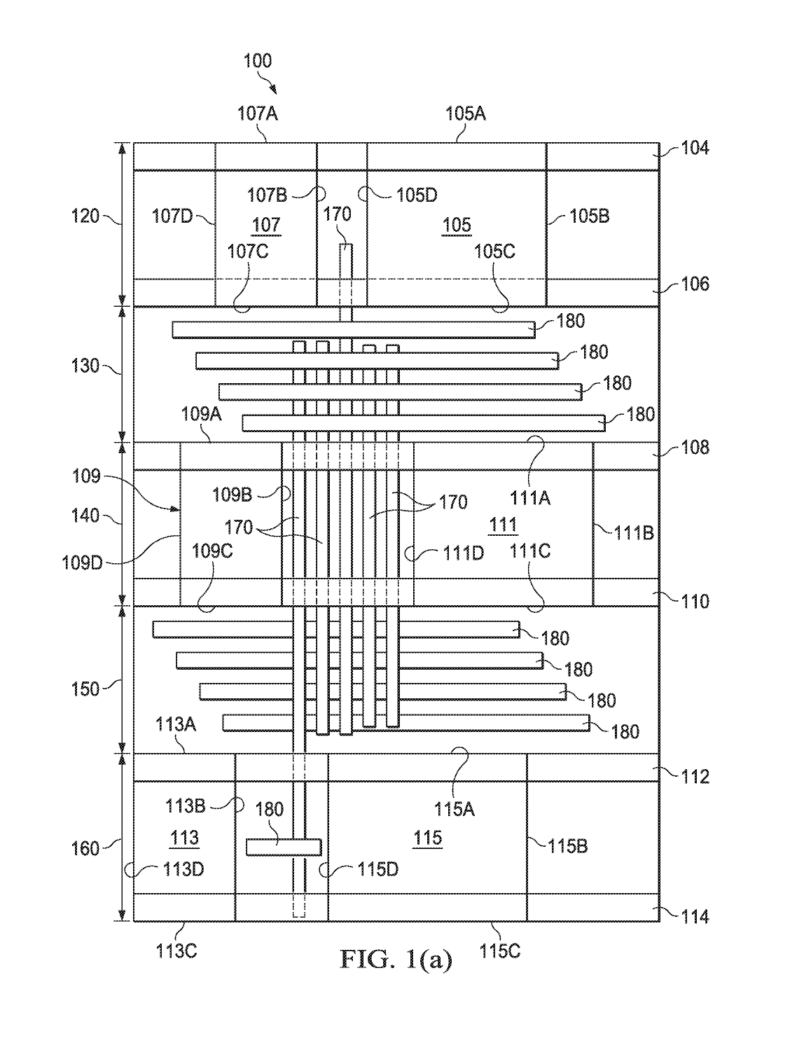

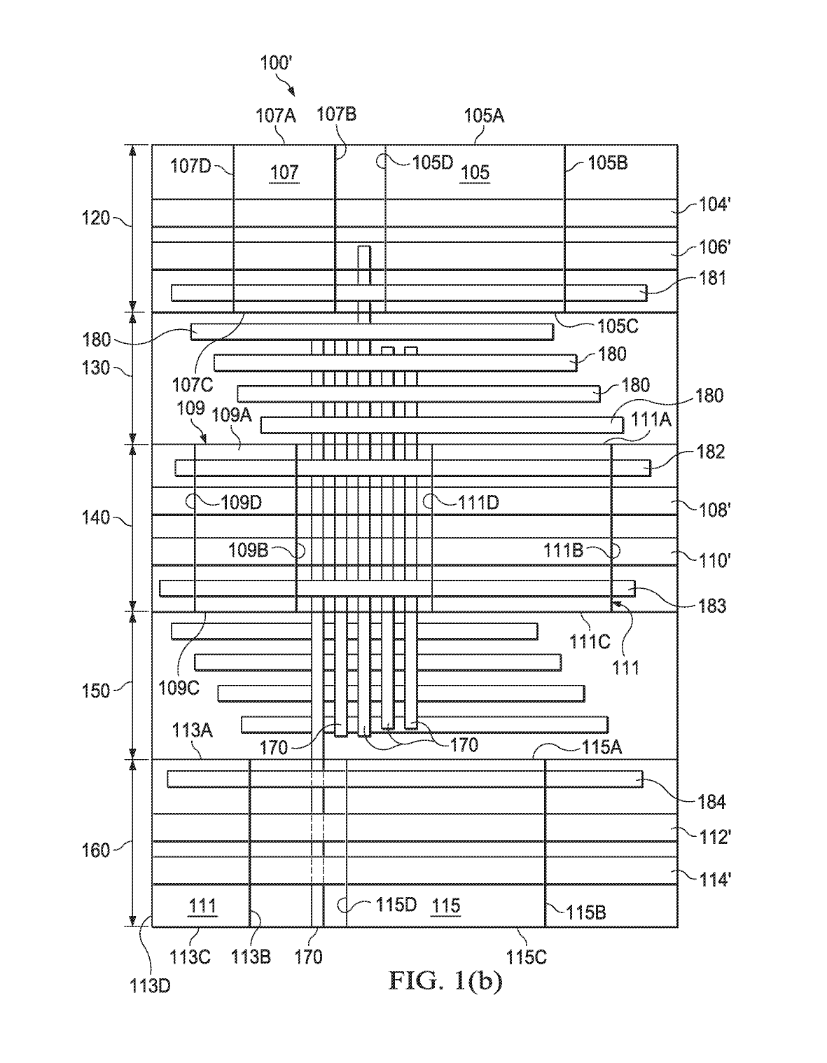

FIG. 1(a) is an illustrative digital block area 100 that employs a single level of met and poly layers to transport signals between multiple digital blocks. In some examples, digital block area 100 may include multiple digital blocks collectively performing a modularized logical function. FIG. 1 includes multiple different regions, such as regions 120, 130, 140, 150, and 160. Regions 120, 140, and 160 are the regions in the digital block area 100 that include multiple digital blocks 105, 107, 109, 111, 113, and 115. In some examples, the digital blocks 105, 107, 109, 111, 113, and 115 are defined using their periphery. For instance, the digital block 105 is defined by a peripheral boundary marked as 105A, 105B, 105C, 105D. Similarly, the digital block 107 is defined by a peripheral boundary marked as 107A, 107B, 107C, 107D. Similarly, the digital block 109 is defined by a peripheral boundary marked as 109A, 109B, 109C, 109D. Similarly, the digital block 111 is defined by a peripheral boundary marked as 111A, 111B, 111C, 111D. The digital block 113 is defined by a peripheral boundary marked as 113A, 113B, 113C, 113D. The digital block 115 is defined by a peripheral boundary marked as 115A, 115B, 115C, 115D. In some examples, each of the digital blocks 105, 107, 109, 111, 113, 115 is in a rectangular shape. In other examples, the digital blocks 105, 107, 109, 111, 113, 115 can assume any rectilinear shape.

FIG. 1(a) further depicts multiple poly global routing layers 170. Each layer 170 runs parallel to the remaining layers 170. One or more of the layers 170 runs between two digital blocks, such as digital blocks 105 and 107, digital blocks 109 and 111, and digital blocks 113 and 115. Regions 130 and 150 are separate regions that provide channels for the met routing layers 180. The met routing layers 180 (which run in parallel with each other) and the poly routing layers 170 (which also run in parallel with each other) are orthogonal to each other. Although FIG. 1(a) depicts the met routing layers 180 running horizontally, in some examples, the met routing layers 180 may switch positions with the poly routing layers 170 and run vertically. In such examples, the poly routing layers 170 may run horizontally in the regions 130, 150.

FIG. 1(a) further depicts a first power rail 104 positioned on the peripheral boundaries 107A, 105A of the digital blocks 107, 105, respectively. Similarly, the first power rails 108 and 112 are positioned on the peripheral boundaries 109A, 111A and 113A, 115A, respectively. FIG. 1(a) also depicts a second power rail 106 positioned on the peripheral boundaries 107C, 105C of the digital blocks 107, 105, respectively. Similarly, the second power rails 110 and 114 are positioned on the peripheral boundaries 109C, 111C and 113C, 115C, respectively.

The first power rails 104, 108, 112 and the second power rails 106, 110, 114 provide power to the digital blocks present in the regions 120, 140, and 160. In some examples, the first power rails 104, 108, 112 may include a high-potential rail, which is configured to receive finite power and the second power rails 106, 110, 114 may include a ground rail. In other examples, the roles may be reversed, i.e., the first power rails 104, 108, 112 may include a ground rail and the second power rails 106, 110, and 114 may include a high-potential rail.

As noted above, the area in a digital block area (such as the digital block area 100) is typically limited and thus space designers also have limited space to design and route multiple digital blocks. FIG. 1(b) depicts an illustrative modified version of the digital block area 100 (FIG. 1(a)) that is adjusted with respect to the position of power rails 104, 106, 108, 110, 112, and 114 of FIG. 1(a). The modified digital block area 100′ includes modified power rails 104′, 106′, 108′, 110′, 112′, and 114′. These modified power rails assume positions that are closer to the center of each of the multiple digital blocks 105, 107, 109, 111, 113, and 115 than they are in FIG. 1(a), e.g., they are positioned closer to the center of the digital blocks than the outermost peripheries of the digital blocks. For example, in FIG. 1(a) the power rails 104 and 106 are positioned along the outermost periphery of the digital blocks 105 and 107. In some examples, however, the power rails may be located farther inside the digital blocks 105 and 107 than shown in FIG. 1(b) to increase the space available for routing layers, such as met layers. Referring to FIG. 1(b), for instance, modified power rails 104′ and 106′ are positioned farther inside (i.e., closer to a center of) the digital block 105 than shown in FIG. 1(a). Similarly, the modified power rails 104′ and 106′ are positioned farther inside the digital block 107 than shown in FIG. 1(a). This positioning provides additional space to facilitate the inclusion of additional routing layers, such as the met layer 181. In some embodiments, the modified power rails are more proximate to a center of a digital block than they are to an outermost periphery of that digital block. Other modified power rails 108′, 110′, 112′, and 114′ may be similarly positioned. This positioning may provide additional space to facilitate the inclusion of additional routing layers, such as the met layers 182, 183, 184. The positions of the modified power rails 104′, 106′, 108′, 110′, 112′, and 114′ is not limited to the positions depicted in FIG. 1(b). As further described below, in other examples, the positions may vary. For instance, in some examples, one power rail (e.g., 106′) of a pair of power rails (e.g., 104′, 106′) may be positioned farther toward the center of a digital block than the outermost periphery of the digital block while the other power rail (e.g., 104′) in the pair of power rails may be positioned on the outermost periphery of the digital block.

The aforementioned description of additional met routing layers 181, 182, 183, and 184, which may assist in providing efficient global routing, may also be understood from a fabrication standpoint. For instance, the modified power rails 104′, 106′, 108′, 110′, 112′, and 114′ and the met layers, such as global met layers 180 and local met layers (not shown) that may be present in the digital blocks 105, 107, 109, 111, 113, and 115, may be positioned in the same plane. Additionally, the poly layers, such as global poly routing layers 170 and local poly layers (not shown) are positioned in a plane below the plane of the met layers (and the modified power rails 104′, 106′, 108′, 110′, 112′, and 114′). As noted above, the met routing layers 180 are positioned to be in the regions 130, 150. In order to prevent a short circuit condition, additional met routing layers may be positioned in the additional space made available by positioning some of the power rails away from the peripheral boundaries of their respective digital blocks.

In some examples, the positions of the power rails over a digital block may depend on the amount of space utilized in the digital block. For instance, assume that the digital block 105 includes a complex logical design, while the digital block 107 includes a relatively simple logical design. In such an example, the digital block 105 may utilize most (if not all) of the space inside the digital block 105. On the contrary, the digital block 107 may not utilize all of the space inside the digital block and thus may have some extra space left. This extraneous space may be further utilized to accommodate additional global met layers 180. That is, in some examples, the more space needed in a digital block to design a logical function, the fewer the number of additional global met layers it may be able to accommodate. On the contrary, the lesser space needed to design a logical function in a digital block, the greater the number of global met layers the digital block may be able to accommodate.

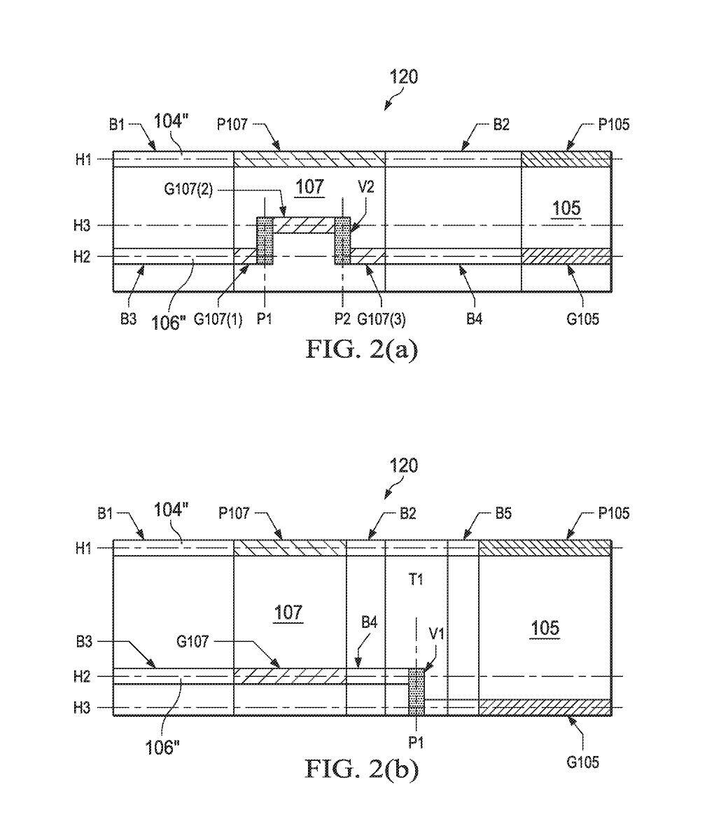

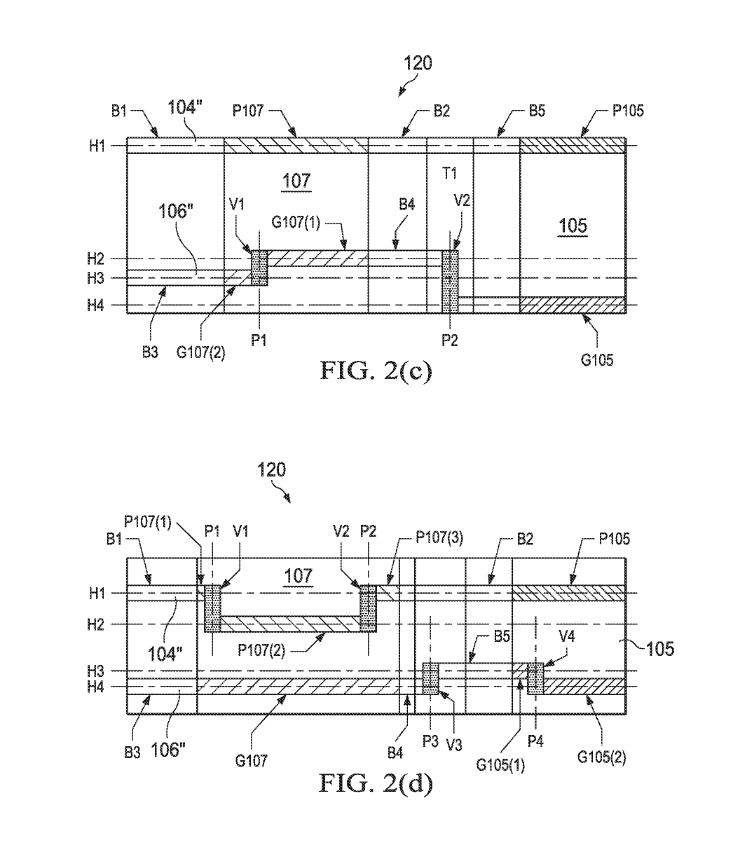

Refer now to FIG. 2(a), which depicts an illustrative region 120 of the modified digital block area 100′ (FIG. 1(b)) that includes the digital block 105, 107. FIG. 2(a) depicts example power rails 104″, 106″. The example power rail 104″ may include multiple portions, such as B1, P107, B2, P105. B1, B2 are the portions that are positioned outside the digital block 107, 105. P107 is the portion that is positioned inside the digital block 107 and P105 is positioned inside the digital block 105. In some examples, the portions B1, P107, B2, and P105 are aligned on the horizontal axis H1. The example power rail 106″ may include the portions B3, G107 (1), V1, G107 (2), V2, B4, and G105. In some examples, the portions B3, B4 are positioned outside the digital blocks 105, 107. In some examples, the portions B3, G107 (1), G107 (2), B4, and G105 may be aligned on the horizontal axis H2. In some examples, the portions G107 (2) may be aligned on the horizontal axis H3. In some examples, jog portions V1, V2 may be positioned on the vertical axes P1, P2 (respectively).

As noted above, the proximity of a power rail to the center of the digital block may vary depending on the space required to design a logical functional in that digital block. Consequently, FIG. 2(a) depicts the positions the different portions of the power rails 104″, 106″ may assume in and/or around the digital blocks 105, 107. For explanation's sake, assume that the digital block 107 may need less space (to design a logical function) than the space the digital block 107 includes. Therefore, in order to increase space availability for met layers, the portion G107 (2) may be positioned closer to the center (as shown) on the horizontal axis H3. On the other hand, depending on the amount of space needed to design a logical function in the digital block 105, the portion G105 may also be positioned closer to the center of the digital block 105 at the horizontal axis H2. To maintain continuity in different portions of the power rail 106″, jog (vertical) portions V1, V2 may be used to couple portions of the power rail 106″ aligned on different horizontal axes. In some examples, the vertical axes P1, P2 may be parallel to each other and perpendicular to the horizontal axes H1, H2. In some examples, the jog portions V1, V2 may be positioned inside the digital block 107.

Now referring to FIG. 2(b), which depicts an illustrative region 120 of the modified digital block area 100′ that includes the digital block 105, 107. FIG. 2(b) further depicts the positions the different portions of the power rails 104″, 106″ may assume in and/or around the digital blocks 105, 107. FIG. 2(b) depicts example power rails 104″, 106″. The example power rail 104″ may include multiple portions, such as B1, P107, B2, P105, where B1, B2 is the portion that is positioned outside the digital block 107, 105. P107 is the portion that is positioned inside the digital block 107 and P105 is positioned inside the digital block 105. In some examples, the portions B1, P107, B2, and P105 are aligned on the horizontal axis H1. The example power rail 106″ may include the portions B3, G107, V1, B4, B5, and G105. In some examples, the portions B3, B4, and B5 are positioned outside the digital blocks 105, 107. In some examples, the portions B3, G107, B4 may be aligned on the horizontal axis H2. In some examples, the portions B5, G105 may be aligned on the horizontal axis H3. In some examples, jog portions V1 may be aligned on the vertical axis P1. Similar to FIG. 2(a), assume that the digital block 107 includes a digital design that does not need complete area of the digital block 107. Therefore, the portion G107 is positioned closer to the center of the digital block 107. In some examples, the digital block 105 may need complete area of the digital block 105, and therefore the portion G105 may be positioned at the periphery of the digital block 105. In order to maintain continuity in all the portions of the power rail 106″ a jog portion, such as V1, may be used to couple with the portions of the power rail 106″ aligned on different horizontal axis.

In some examples, the digital block 107 may not have enough space to include a jog portion in the digital block itself. In such an example, a transition block, such as T1, may be used to include the jog portion V1. A transition block is generally defined as an area outside of a digital block that includes a jog portion. A transition block may include one or more vertical layers, such as a substrate, met layers, and poly layers, but, at a minimum, it includes one or more jog portions of a power rail. A transition block may not be explicitly identified in a fabricated IC. However, since the final fabricated IC may be derived from the masks that are designed using the cell-based methodology, the scope of the transition block is not limited to the layouts described in this disclosure, but also includes the fabricated IC.

The jog portion V1 may be aligned to the vertical axis P1. In some examples, the vertical axis P1 is perpendicular to the horizontal axis H1, H2. Now referring back to FIG. 2(a), in some examples, one of the jog portions V1, V2 may be included in separate transition block (not shown), such that one of the jog portions, for instance, V1, is positioned inside the digital block 107. Whereas, the jog portion V2 is positioned in a separate transition block (not shown).

Now refer to FIG. 2(c), which depicts an illustrative region 120 of the modified digital block area 100′ that includes the digital block 105, 107. FIG. 2(c) depicts example power rails 104″, 106″. FIG. 2(c) further depicts the positions the different portions of the power rails 104″, 106″ may assume in and/or around the digital blocks 105, 107. FIG. 2(b) depicts example power rails 104″, 106″. Similar to FIGS. 2(a), 2(b), the example power rail 104″ may include multiple portions, such as B1, P107, B2, P105. B1, B2 are the portions that are positioned outside the digital block 107, 105. P107 is the portion that is positioned inside the digital block 107 and P105 is positioned inside the digital block 105. In some examples, the portions B1, P107, B2, and P105 are aligned on the horizontal axis H1. The example power rail 106″ may include the portions B3, G107 (1), G107 (2), V1, V2, B4, B5, and G105. In some examples, the portions B3, B4, and B5 are positioned outside the digital blocks 105, 107. In some examples, the portions B3, G107 (2) may be aligned on the horizontal axis H3. In some examples, the portions B5, G105 may be aligned on the horizontal axis H4. In some examples, the portions B4, G107 (1) may be aligned on the horizontal axis H2. In some examples, jog portions V1 may be aligned on the vertical axis P1. Similar to FIG. 2(a), assume that the digital block 107 includes a digital design that does not need complete area of the digital block 107. Therefore, the portion G107 is positioned closer to the center of the digital block 107. In some examples, the digital block 105 may need complete area of the digital block 105, and therefore the portion G105 may be positioned at the periphery of the digital block 105. In order to maintain continuity in all the portions of the power rail 106″, jog portions, such as V1, V2 may be used to couple with the portions of the power rail 106″ aligned on different horizontal axis.

In some examples, the jog portion V1 may be included in the digital block 107. In some examples, the jog portion V1 may be positioned outside the digital block 107 in another transition block (not shown). In some examples, the jog portion V2 may be included in a transition block T1. In some examples, the jog portion V2 may be included in the digital block 105 (not shown). The vertical axes P1, P2 are parallel to each other. Furthermore, the vertical axes P1, P2 are perpendicular to the horizontal axis H1, H2, and H3. In some examples, the power rail 104″ may also include jog portions as described for the power rail 106″.

Referring now to FIG. 2(d), which depicts an illustrative region 120 of the modified digital block area 100′ that includes the digital block 105, 107. FIG. 2(d) depicts example power rails 104″, 106″. The example power rail 104″ may include multiple portions, such as B1, P107 (1), P107 (2), P107 (3), V1, V2, B2, and P105. B1, B2 are the portions that are positioned outside the digital block 107, 105. P107 (1), P107 (2), and P107 (3) are the portions that are positioned inside the digital block 107, and P105 is positioned inside the digital block 105. In some examples, the portions B1, P107 (1), B2, and P105 are aligned on the horizontal axis H1. Whereas, the portion P107 (2) may be aligned on the horizontal axis H2. The portions V1, V2 may be aligned on the vertical axis P1, P2 respectively.

The example power rail 106″ may include the portions B3, G107, B4, V3, B5, G105 (1), V4, and G105 (2). In some examples, the portions B3, B4, B5 may be positioned outside the digital blocks 105, 107. In some examples, the portions B3, B4, G107, and G105 (2) may be aligned on the horizontal axis H4. In some examples, the portions G105 (1) and B5 may be aligned on the horizontal axis H3. In some examples, jog portions V3, V4 may be positioned on the vertical axes P3, P4 (respectively).

As noted above, the proximity of a power rail to the center of the digital block may vary depending on the space required to design a logical function in that digital block. Consequently, FIG. 2(d) depicts the positions the different portions of the power rails 104″, 106″ may assume in and/or around the digital blocks 105, 107. For explanation's sake, assume that the digital block 107 may need less space (to design a logical function) than the space the digital block 107 includes. Therefore, in order to increase space availability for met layers, the portion G107 and P107 (2) may be positioned closer to the center (as shown). On the other hand, depending on the amount of space needed to design a logical function in the digital block 105, the portion G105 (1), G105 (2) may also be positioned closer to the center of the digital block 105. To maintain continuity in different portions of the power rail 104″, jog portions V1, V2 may be used to couple portions of the power rail 104″ that are aligned on different horizontal axes. Similarly, to maintain continuity in different portions of the power rail 106″, jog (vertical) portions V3, V4 may be used to couple portions of the power rail 106″ aligned on different horizontal axes. In some examples, the jog portions V1, V2 may be positioned inside the digital block 107. In some examples, the jog portion V1 may be positioned in a separate transition block (not shown). In some examples, the jog portion V3 is positioned in a transition block T1. In some examples, the jog portion V4 is positioned in the digital block 105.

FIGS. 1(a)-2(d) depict various examples illustrative of the power rail-positioning technique described herein. The scope of this disclosure, however, is not limited to the specific examples depicted in FIGS. 1(a)-2(d) and described herein. All variations of the power rail-positioning technique described herein are contemplated and fall within the scope of this disclosure.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

1. An apparatus, comprising:
a first digital block;
a second digital block; and
a continuous power rail, the continuous power rail comprising a first portion, extending through the first digital block, that is aligned along a first axis, and the continuous power rail further comprising a second portion, extending through the second digital block, that is aligned along a second axis, wherein the first and the second axes are parallel to each other.

2. The apparatus of claim 1, wherein the apparatus uses a poly layer as a routing layer, and wherein the poly layer is configured to route a signal between the first digital block and the second digital block.

3. The apparatus of claim 1, wherein the continuous power rail comprises a jog portion to couple the first portion to the second portion.

4. The apparatus of claim 3, wherein the jog portion is aligned along a third axis that is orthogonal to the first and second axes.

5. The apparatus of claim 3, wherein the jog portion is positioned in the first digital block.

6. The apparatus of claim 3, wherein the jog portion is positioned outside the first digital block.

7. The apparatus of claim 3 further comprising a transition block, wherein the jog portion is positioned in the transition block.

8. The apparatus of claim 1, wherein the continuous power rail further comprises a first jog portion aligned on a first vertical axis and a second jog portion aligned on a second vertical axis, wherein the first and second vertical axes are parallel to each other, and the first and the second vertical axes are perpendicular to the first and second horizontal axes.

9. The apparatus of claim 8, wherein the first and second jog portions are positioned in the first digital block.

10. The apparatus of claim 8, wherein the first jog portion is positioned in the first digital block and the second jog portion is positioned in the second digital block.

11. The apparatus of claim 8, wherein the first jog portion is positioned in the first digital block and the second jog portion is positioned in a transition block.

12. An apparatus, comprising:
a digital block; and
a power rail comprising a first portion aligned along a first axis, a second portion aligned along a second axis, and a third portion aligned along a third axis that is orthogonal to the first and second axes, the third portion couples to the first portion and the second portion.

13. The apparatus of claim 12, wherein the power rail comprises a fourth and a fifth portion, wherein the fourth portion is aligned along the second axis and the fifth portion is aligned along a fourth axis that is orthogonal to the first and second horizontal axes, wherein the fifth portion couples with the first and the fourth portions.

14. The apparatus of claim 13, wherein the first, second, third, fourth and fifth portions are positioned inside the digital block.

15. The apparatus of claim 13, wherein the fifth portion is positioned in a transition block.

16. The apparatus of claim 12, wherein the power rail comprises a fourth and a fifth portion, wherein the fourth portion is aligned along a fourth axis and the fifth portion is aligned along a fifth axis that is orthogonal to the first, second, and fourth horizontal axes, wherein the fifth portion couples with the first and the fourth portions.

17. An apparatus, comprising:
a digital block;
a first power rail positioned inside a first peripheral boundary of the digital block comprising a first, a second, and a third portion, the first portion aligned along a first axis, the second portion aligned along a second axis, the third portion aligned along a third axis that is orthogonal to the first and second axes, the third portion couples the first portion and the second portion; and
a second power rail positioned inside a second peripheral boundary of the digital block comprising a fourth, a fifth, and a sixth portion, the fourth portion aligned along a fourth axis, the fifth portion aligned along a fifth axis, the sixth portion aligned along a sixth axis that is orthogonal to the fourth and fifth axes, the sixth portion couples to the fifth portion and the sixth portion.

18. The apparatus of claim 17, wherein a seventh portion couples the first portion and the second portion, the seventh portion is positioned in a transition block that shares a peripheral boundary with the digital block.

19. The apparatus of claim 17, wherein an eighth portion couples the fifth portion and the sixth portion, the eighth portion is positioned in a transition block that shares a peripheral boundary with the digital block.

20. The apparatus of claim 17, wherein the first power rail is configured to provide a finite voltage to the digital block, wherein the second power rail is configured to provide the digital block with a ground.
